(19) United States
(12) Patent Application Publication
(10) Pub. No.: US 2024/0038551 A1
(43) Pub. Date: Feb. 1, 2024

(54) COATING COMPOSITION FOR WAFER PROTECTION AND METHOD OF MANUFACTURING SEMICONDUCTOR PACKAGE USING THE SAME

(71) Applicant: SAMSUNG ELECTRONICS CO., LTD., Suwon-si (KR)

(72) Inventors: Woojung PARK, Suwon-si (KR); Mihyae PARK, Suwon-si (KR)

(21) Appl. No.: 18/225,768

(22) Filed: Jul. 25, 2023

(30) Foreign Application Priority Data
Aug. 1, 2022 (KR) 10-2022-0095687

(51) Int. Cl. H01L 21/56; C09D 7/20; H01L 21/02; C09D 7/61; C09D 5/16; H01L 21/304

(52) U.S. Cl. CPC H01L 21/561; C09D 7/20; H01L 21/02076; C09D 7/61; C09D 5/1637; H01L 21/304; H01L 21/02016

(57) ABSTRACT

A coating composition for wafer protection and a method of manufacturing a semiconductor package, the coating composition includes a solvent; about 1 weight percent (wt %) to about 40 wt % of a water-soluble polymer; and about 0.01 wt % to about 30 wt % of a nano light-emitting filler.

### CROSS-REFERENCE TO RELATED APPLICATION

This application is based on and claims priority under 35 U.S.C. § 119 to Korean Patent Application No. 10-2022-0095687, filed on Aug. 1, 2022, in the Korean Intellectual Property Office, the disclosure of which is incorporated by reference herein in its entirety.

### BACKGROUND

### 1. Field

Embodiments relate to a coating composition for wafer protection and a method of manufacturing a semiconductor package using the coating composition.

### 2. Description of the Related Art

A wafer may provide a plurality of semiconductor chips through a dicing process. The dicing process may be a process of dicing (or cutting) the wafer to obtain a plurality of semiconductor chips.

### SUMMARY

The embodiments may be realized by providing a coating composition for wafer protection, the coating composition including a solvent; about 1 weight percent (wt %) to about 40 wt % of a water-soluble polymer; and about 0.01 wt % to about 30 wt % of a nano light-emitting filler.

The embodiments may be realized by providing a method of manufacturing a semiconductor package, the method including preparing a wafer including a circuit layer or a wiring layer; forming a wafer protective layer by coating a coating composition for wafer protection on the wafer, the coating composition for wafer protection including a solvent, about 1 weight percent (wt %) to about 40 wt % of a water-soluble polymer, and about 0.01 wt % to about 30 wt % of a nano light-emitting filler; dicing the wafer on which the wafer protection layer is formed, into semiconductor chips; and removing the wafer protective layer from the semiconductor chips by primary cleaning the wafer protective layer; wherein primary cleaning the wafer protective layer includes detecting residual material remaining on the semiconductor chips.

The embodiments may be realized by providing a method of manufacturing a semiconductor package, the method including preparing a wafer including a circuit layer or a wiring layer; mounting the wafer on a first support film; forming a wafer protective layer by coating a coating composition for wafer protection on the wafer, the coating composition for wafer protection including a solvent, about 1 weight percent (wt %) to about 40 wt % of a water-soluble polymer, and about 0.01 wt % to about 30 wt % of a nano light-emitting filler; dicing the wafer, on which the wafer protection layer has been formed, into semiconductor chips; separating the semiconductor chips by expanding the first support film; transferring and mounting the separated semiconductor chips onto a second support film; and removing the wafer protective layer from the semiconductor chips mounted on the second support film by primary cleaning the wafer protective layer; wherein primary cleaning the wafer protective layer includes detecting residual material remaining on the semiconductor chips.

### BRIEF DESCRIPTION OF THE DRAWINGS

Features will be apparent to those of skill in the art by describing in detail exemplary embodiments with reference to the attached drawings in which:

FIG. 1 is a flowchart of a method of manufacturing a semiconductor package according to an embodiment;

FIGS. 2 to 6 are perspective views of stages in the method of manufacturing the semiconductor package of FIG. 1;

FIGS. 7A and 7B are graphs illustrating the intensity of emitted light depending on the excitation wavelength of a nano light-emitting filler included in a coating composition for wafer protection used in a method of manufacturing a semiconductor package of an embodiment;

FIGS. 8A and 8B are graphs illustrating the intensity of emitted light depending on the emission wavelength of a nano light-emitting filler included in a coating composition for wafer protection used in a method of manufacturing a semiconductor package of an embodiment;

FIGS. 9 and 10 are cross-sectional views of stages in a dicing process included in a method of manufacturing a semiconductor package of an embodiment;

FIG. 11 is a flowchart of a method of manufacturing a semiconductor package according to an embodiment;

FIGS. 12 and 13 are perspective views of stages in the method of manufacturing the semiconductor package of FIG. 11;

FIGS. 14 to 21 are cross-sectional views of stages in a method of manufacturing a semiconductor package according to an embodiment;

FIG. 22 is a cross-sectional view of a semiconductor chip that may be manufactured by a method of manufacturing a semiconductor package according to an embodiment;

FIG. 23 is a cross-sectional view of a semiconductor chip that may be manufactured by a method of manufacturing a semiconductor package according to an embodiment;

FIG. 24 is a cross-sectional view of a package process included in a method of manufacturing a semiconductor package according to an embodiment;

FIG. 25 is a cross-sectional view of a package process included in a method of manufacturing a semiconductor package according to an embodiment;

FIG. 26 is a cross-sectional view showing a semiconductor package manufactured by a method of manufacturing a semiconductor package according to an embodiment; and

FIGS. 27 and 28 are views of a semiconductor package manufactured by a method of manufacturing a semiconductor package according to an embodiment.

### DETAILED DESCRIPTION

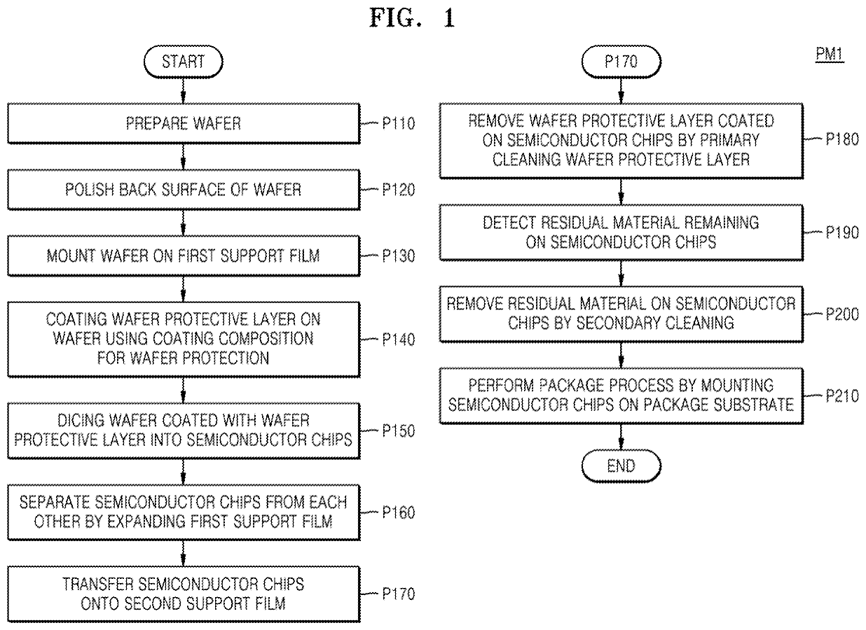

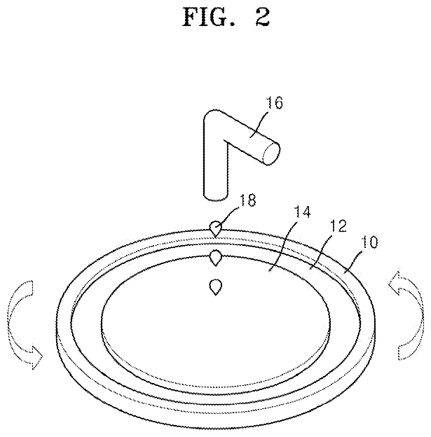

FIG. 1 is a flowchart of a method of manufacturing a semiconductor package according to an embodiment, and FIGS. 2 to 6 are perspective views of stages in the method of manufacturing the semiconductor package of FIG. 1.

In an implementation, in operation P110, the semiconductor package manufacturing method PM1 may include preparing a wafer (14 of FIG. 2) including a circuit layer (or an integrated circuit layer). In an implementation, a circuit layer may not be formed on the wafer (14 in FIG. 2) and only a wiring layer may be formed. The wafer may include a semiconductor element, e.g., silicon (Si) or germanium (Ge), or a compound semiconductor, e.g., silicon carbide (SiC), gallium arsenide (GaAs), indium arsenide (InAs), indium phosphide (InP), or the like. Operation P110 may be a wafer process. As used herein, the term “or” is not an exclusive term, e.g., “A or B” would include A, B, or A and B.

In operation P120, the back surface of the wafer 14 may be polished. The backside polishing of the wafer 14 may be a process of reducing the thickness of the wafer by polishing the backside of the wafer by a grinding method. The backside polishing of the wafer 14 may facilitate the subsequent dicing process. The backside polishing of the wafer 14 may be performed to help reduce the thickness of the semiconductor chips. The backside polishing of the wafer 14 is described in more detail below. Operation P120 may be the backside polishing process of the wafer.

Subsequently, operations P120 to P200 may be semiconductor chip division (separation) processes. In operation P130, the wafer 14 may be mounted on a first support film 12. As shown in FIG. 2, the wafer 14 may be mounted on the first support film 12 positioned on a support frame 10. In operation P140, a wafer protective layer may be formed by coating a coating composition 18 for wafer protection on the wafer 14 mounted on the first support film 12. The wafer protective layer may be formed by, e.g., a spin coating method.

In an implementation, the coating composition 18 for wafer protection may be discharged onto the wafer 14 through a coating nozzle 16. The discharged coating composition 18 for wafer protection may be uniformly coated on the wafer 14 by rotating the support frame 10. Here, the coating composition 18 for wafer protection is described.

The coating composition 18 for wafer protection may include, e.g., a solvent; about 1 weight percent (wt %) to about 40 wt % of a water-soluble polymer; and about 0.01 wt % to about 30 wt % of a nano light-emitting filler (wt % being based on a total weight of the coating composition). In an implementation, the coating composition 18 for wafer protection may include about 1 wt % to about 40 wt % of a water-soluble polymer, about 0.01 wt % to about 30 wt % of a nano light-emitting filler, and the balance of a solvent, based on a total weight thereof.

In an implementation, the coating composition 18 for wafer protection may have a viscosity of, e.g., about 10 cP to about 500 cP. The viscosity is measured at a room temperature, i.e., 20±5° C. In an implementation, the solvent may include, e.g., water or an alcohol. In an implementation, the water-soluble polymer may include, e.g., polyvinyl alcohol (PVA), polyvinyl pyrrolidone (PVP), polyethylene glycol (PEG), cellulose, polyoxazoline, polyacrylic acid (PAA), polyacrylamide, or combinations thereof.

In an implementation, the nano light-emitting filler may include, e.g., Li, Na, K, Mg, Ca, Sr, Ba, Ti, Zr, Hf, V, Nb, Ta, Cr, Mo, W, Mn, Fe, Ru, Co, Ni, Pd, Pt, Cu, Ag, Au, Zn, B, Al, Ga, In, Si, Ge, Sn, As, Bi, La, Ce, Pr, Gd, Yb, Tb, Lu, Sm, or combinations thereof. In an implementation, the nano light-emitting filler may further include, e.g., C, N, O, P, S, F, Cl, Br, Se, Te, or combinations thereof, in addition to the aforementioned material.

In an implementation, the nano light-emitting filler may include, e.g., SiO₂, Al₂O₃, ZnO, Ga₂O₃, MgO, TiO₂, an Ag compound, Fe₂O₃, Fe₃O₄, or a Cu compound.

In an implementation, the nano light-emitting filler may include, e.g., an organic phosphor, an inorganic phosphor, a quantum dot (QD), or a thermochromic pigment. In an implementation, the phosphor may have the following compositional formula and color.

Oxide: blue, yellow, green and red, Y₂O₃:Eu, Y₂O₃:Eu,Bi, CaO: Eu, BaAlO:Eu, Y₃Al₅O₁₂:Ce, Tb₃Al₅O₁₂:Ce, Lu₃Al₅O₁₂:Ce

Silicate: yellow and green (Ba,Sr)₂SiO₄:Eu, yellow and orange (Ba,Sr)₃SiO₅:Ce

Nitride: green β-SiAlON:Eu, yellow La₃Si₆N₁₁:Ce, orange α-SiAlON:Eu, red CaAlSiN₃:Eu, Sr₂Si₅N₈:Eu, SrSiAl₄N₇:Eu, SrLiAl₃N₄:Eu,

Ln₄₋ₓ(Eu_{z}M_{1-z})ₓSi_{12-y}AlyO_{3+x+y}N_{18-x-y}(0.5≤x≤3, 0<z<0.3, 0<y≤4) Formula (1)

In Formula (1), Ln may be, e.g., a group IIIa element of the periodic table of elements or a rare earth element, and M may be, e.g., Ca, Ba, Sr, or Mg.

Fluoride: KSF-based red K₂SiF₆:Mn⁴⁺, K₂TiF₆:Mn⁴⁺, NaYF₄:Mn⁴⁺, NaGdF₄:Mn⁴⁺, K₃SiF₇:Mn⁴⁺

A phosphor composition should basically conform to stoichiometry, and each element may be substituted with another element in a same group on the periodic table. In an implementation, Sr may be substituted with Ba, Ca, Mg, or the like of the alkaline earth (II) group, and Y may be substituted with lanthanide Tb, Lu, Sc, Gd, or the like.

In an implementation, an activator Eu, or the like may be substituted with Ce, Tb, Pr, Er, Yb, or the like, depending on the desired energy level, and the activator alone or a co-active agent for modifying properties may be additionally applied. In an implementation, each of the fluorite red phosphors may be coated with a Mn-free fluoride to help improve reliability at high temperature/high humidity, or may further include an organic coating on the phosphor surface or the Mn-free fluoride coating surface.

A quantum dot (QD) may have a core-shell structure using a III-V or II-VI group compound semiconductor. In an implementation, the QD may have a core, such as CdSe or InP and a shell, such as ZnS or ZnSe. In an implementation, the quantum dots may include a ligand for stabilizing the core and the shell. In an implementation, a diameter of the core may be, e.g., about 1 nm to about 30 nm or about 3 nm to about 10 nm, and a thickness of the shell may be, e.g., about 0.1 nm to about 20 nm or about 0.5 nm to about 2 nm. The thermochromic pigment may include, e.g., Cu, Ni, Hg, Co, Mn, VO (vanadium oxygen) compound, PO (phosphorus oxygen) compound, I, NH (nitrogen hydrogen) compound, CH (carbon hydrogen) compound, or CO (carbon oxygen) compound, as well as a raw material exhibiting a color.

In an implementation, the nano light-emitting filler may have a nano size. The size (e.g., particle diameter) of the nano light-emitting filler may be, e.g., about 1 nm to about 999 nm. In an implementation, the nano light-emitting filler may be excited by ultraviolet light to emit visible light.

In an implementation, the nano light-emitting filler may have an excitation wavelength of, e.g., about 200 nm to about 450 nm. In an implementation, the nano-emission filler may have an emission wavelength of, e.g., about 390 nm to about 650 nm, and a full width at half maximum (FWHM) of the emission wavelength may be about 2 nm to about 130 nm.

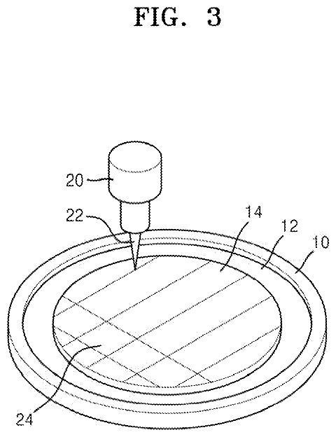

Subsequently, the semiconductor package manufacturing method PM1 may include an operation P150 of dicing the wafer 14 coated with the wafer protective layer into semiconductor chips 24. As shown in FIG. 3, a laser 22 may be applied to the wafer 14 coated with the wafer protective layer using a laser dicing apparatus 20 to dice the wafer 14 into semiconductor chips 24. A dicing method using the laser dicing apparatus 20 is described in more detail below.

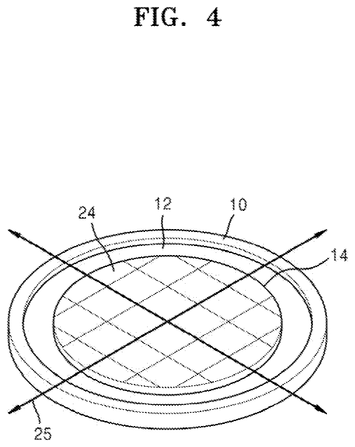

In operation P160, the semiconductor chips 24 may be separated from each other by expanding the first support film 12. As shown in FIG. 4, the first support film 12 may be extended in the direction of an arrow 25 to widen a gap between the diced semiconductor chips 24. The expansion process of the first support film 12 may separate the semiconductor chips 24 from each other and facilitate the subsequent transfer of the semiconductor chips 24.

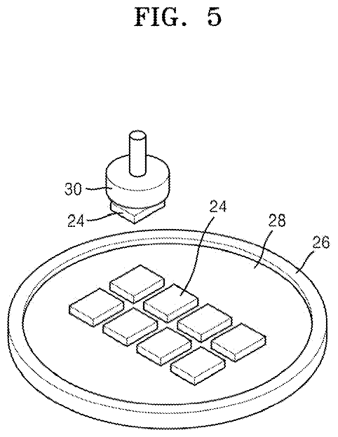

In operation P170, the semiconductor chips 24 may be transferred onto a second support film 28. As shown in FIG. 5, the semiconductor chips 24 may be transferred onto the second support film 28 on a support frame 26 using a pickup device 30. The process of transferring the semiconductor chips 24 onto the second support film 28 may facilitate transfer of the semiconductor chips 24 mounted on the package substrate. In an implementation, the process of transferring the semiconductor chips 24 onto the second support film 28 may help prevent foreign substances or contaminants generated during the dicing process from being included in the semiconductor package.

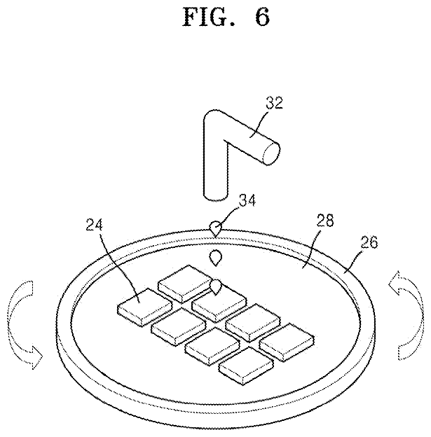

In operation P180, the wafer protective layer on the semiconductor chips 24 may be removed by primary cleaning the wafer protective layer. As shown in FIG. 6, the semiconductor chips 24 may be mounted on the second support film 28 on the support frame 26. A cleaning solution 34 may be discharged (using a cleaning nozzle 32) onto the semiconductor chips 24 mounted on the second support film 28. The cleaning solution 34 may include, e.g., water or an alcohol.

The cleaning solution 34 may be uniformly discharged onto the semiconductor chips 24 mounted on the second support film 28 by rotating the support frame 26. Accordingly, the wafer protective layer on the semiconductor chips 24 may be removed.

Subsequently, in operation P190, the semiconductor package manufacturing method PM1 may detect whether any residual material remains on the semiconductor chips 24. The detection of residual material remaining on the semiconductor chips 24 may be performed by irradiating light of a specific wavelength, e.g., about 200 nm to about 450 nm, onto the semiconductor chips 24, and using or detecting light of a specific wavelength, e.g., about 390 nm to about 650 nm emitted on or from the semiconductor chips 24. The irradiated light may include an ultraviolet range, and the emitted light may include a visible light range.

The residual material may be a material of the wafer protective layer that is left behind, e.g., without being completely cleaned. The remaining material may include the nano light-emitting filler of the coating composition for wafer protection. Of the wafer protective layer, the nano light-emitting filler may be excited by ultraviolet light, and the excited nano light-emitting filler may emit visible light. Residual materials remaining on the semiconductor chips may be detected or observed using or due to the emitted visible light.

In an implementation, the size detection or observation of the residual material remaining on the semiconductor chips 24 may be performed using an atomic force microscope (AFM), a nanoscale infrared (nanoIR) spectroscopy, or an energy dispersive spectrometer (EDS).

In operation P200, the residual material on the semiconductor chips 24 may be removed by secondary cleaning. As shown in FIG. 6, the secondary cleaning may be performed by discharging the cleaning solution 34 onto the semiconductor chips 24 using the cleaning nozzle 32.

Subsequently, in operation P210, a package process may be performed by mounting semiconductor chips on the package substrate. The package process may include a semiconductor chip pickup process, a die (semiconductor chip) bonding process, a wire bonding process, and a molding process. A semiconductor package may be completed through such a process.

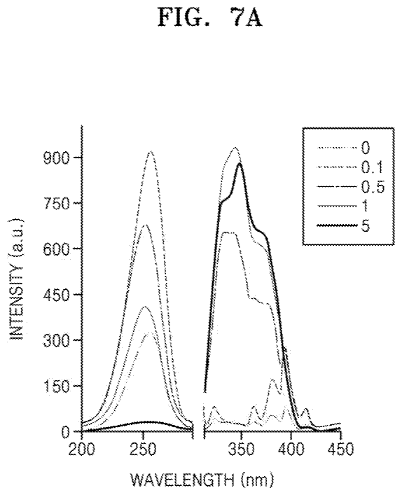

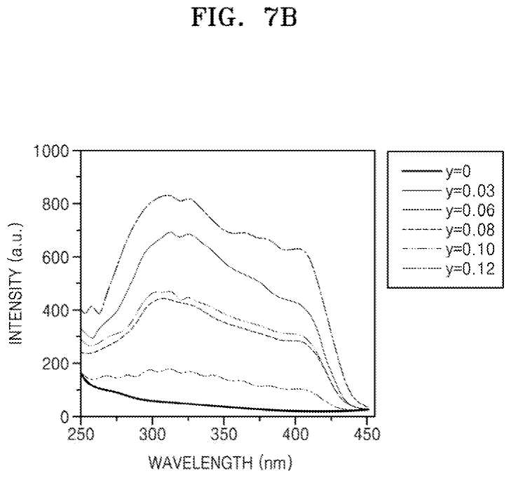

FIGS. 7A and 7B are graphs illustrating the intensity of emitted light depending on the excitation wavelength of a nano light-emitting filler included in a coating composition for wafer protection used in a method of manufacturing a semiconductor package of an embodiment.

FIG. 7A is an emission graph of a nano light-emitting filler including phosphors, such as Y₂O₃:Eu or Y₂O₃:Eu,Bi, and FIG. 7B is an emission graph of a nano light-emitting filler including phosphors such as, CaO:Eu. In FIGS. 7A and 7B, the X-axis shows the excitation wavelength of the nano light-emitting filler, and the Y-axis shows the intensity of emitted light according to the excitation wavelength. The unit of the Y-axis may be any, e.g., an arbitrary, unit.

As shown in FIG. 7A, the nano light-emitting filler may emit light after exposure to light in an excitation wavelength range of about 200 nm to about 450 nm. The wavelength of the emitted light may be about 613 nm. In FIG. 7A, each line corresponds to the mole fraction of Bi.

As shown in FIG. 7B, the nano light-emitting filler may emit light after exposure to light in an excitation wavelength range of about 250 nm to about 450 nm. The wavelength of the emitted light may be about 460 nm. In FIG. 7B, each line corresponds to the mole fraction of Eu. In FIG. 7B, y represents the mole fraction of Eu.

As shown in FIGS. 7A and 7B, in the nano light-emitting filler, even when light having an excitation wavelength of about 200 nm to about 450 nm is applied or irradiated, emitted light may be generated. The nano light-emitting filler of this embodiment may use or absorb light of about 200 nm to about 450 nm as an excitation wavelength. The excitation wavelength may include the ultraviolet range.

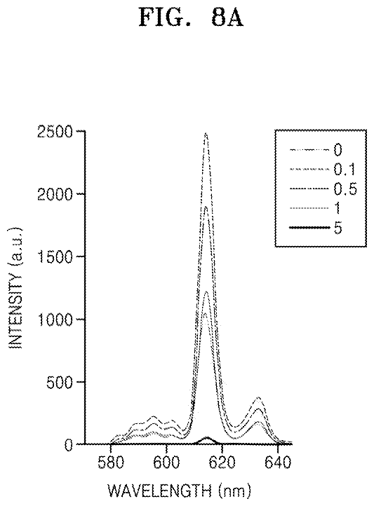

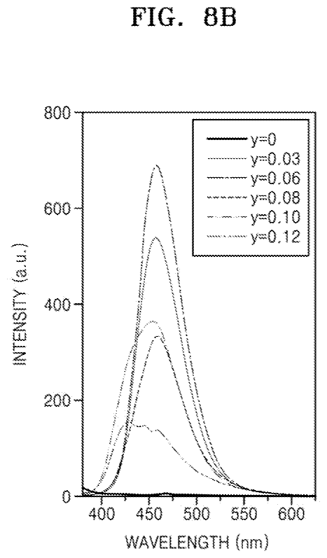

FIGS. 8A and 8B are graphs illustrating the intensity of emitted light depending on the emission wavelength of a nano light-emitting filler included in a coating composition for wafer protection used in a method of manufacturing a semiconductor package of an embodiment.

In detail, FIG. 8A is an emission graph of a nano light-emitting filler including phosphors, such as Y₂O₃:Eu or Y₂O₃:Eu,Bi, and FIG. 8B is an emission graph of a nano light-emitting filler including phosphors such as, CaO:Eu. In FIGS. 8A and 8B, the X-axis shows the emission wavelength of the nano light-emitting filler, and the Y-axis shows the intensity of light according to the emission wavelength. The unit of the Y-axis may be any unit.

As shown in FIG. 8A, the nano light-emitting filler may emit light in an emission wavelength range of about 580 nm to about 650 nm. In FIG. 8A, the excitation wavelength for light generation was about 254 nm. In FIG. 8A, each line corresponds to the mole fraction of Bi.

As shown in FIG. 8B, the nano light-emitting filler may generate light in an emission wavelength range of about 390 nm to about 600 nm. In FIG. 8A, the excitation wavelength for light generation was about 365 nm. In FIG. 8B, y represents the mole fraction of Eu.

As shown in FIGS. 8A and 8B, the emission wavelength of the emitted light of the nano light-emitting filler may be about 390 nm to about 650 nm. The emission wavelength of the nano light-emitting filler according to the present embodiment may include a visible light range. In addition, a full width at half maximum of the emission wavelength of the nano light-emitting filler according to the present embodiment may be about 2 nm to about 130 nm. As shown in FIGS. 8A and 8B, red light or blue light may be emitted when ultraviolet light is applied or irradiated onto the nano light-emitting filler.

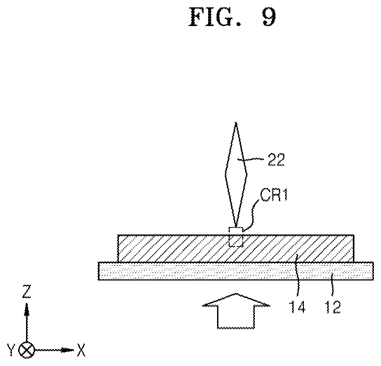

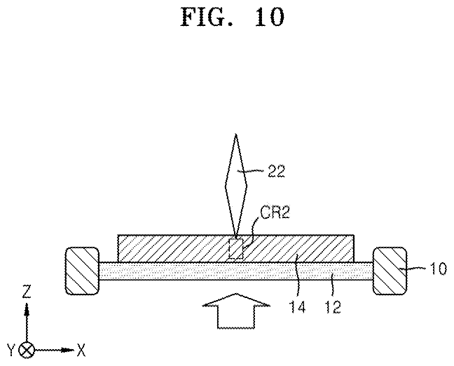

FIGS. 9 and 10 are cross-sectional views of stages in a dicing process included in a method of manufacturing a semiconductor package of an embodiment.

In detail, FIGS. 9 and 10 are provided to illustrate the dicing operation P150 of FIG. 1. FIG. 9 illustrates a laser dicing method. As shown in FIG. 9, the wafer 14 may be mounted on the first support film 12, and the laser 22 may be applied onto the wafer 14. By the laser 22, a cutting region CR1 may be formed on a surface portion of the wafer 14. The cutting region CR1 may extend into the wafer 14 so that the wafer 14 may be separated into semiconductor chips. In the laser dicing, the laser wavelength may be, e.g., about 300 nm to about 700 nm.

FIG. 10 illustrates a stealth laser dicing method. As shown in FIG. 10, the wafer 14 may be mounted on the first support film 12, and the laser 22 is applied on the wafer 14. By the laser 22, a cutting region CR2 may be formed in an inner portion or interior of the wafer 14. In an implementation, when the stealth laser dicing method is used, the semiconductor chips may be separated by applying pressure to the expanded first support film 12 fixed to the support frame 10 in a subsequent process. In the stealth laser dicing, the laser wavelength may be, e.g., about 900 nm to about 1,500 nm.

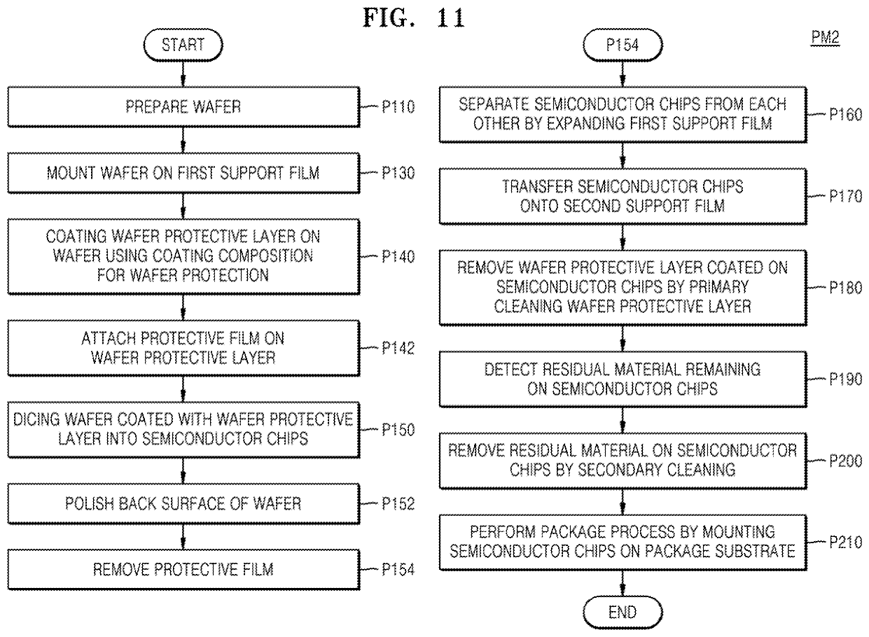

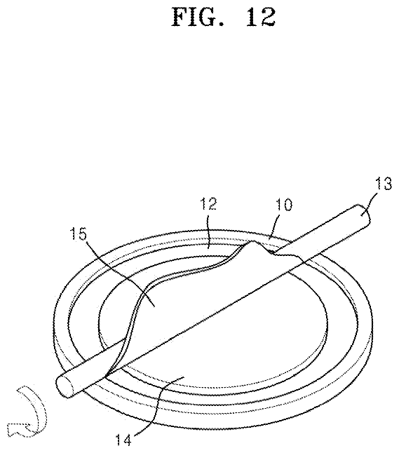

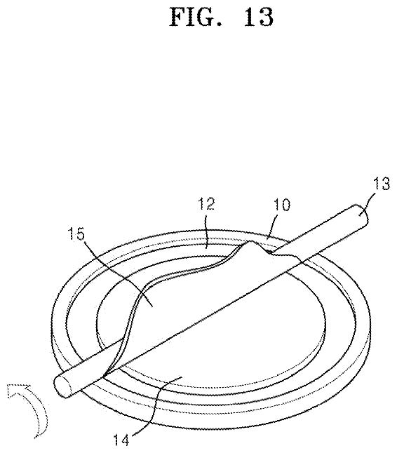

FIG. 11 is a flowchart of a method of manufacturing a semiconductor package according to an embodiment, and FIGS. 12 and 13 are perspective views of stages in the method of manufacturing the semiconductor package of FIG. 11.

In an implementation, when compared to the semiconductor package manufacturing method PM1 of FIGS. 1 to 6, the semiconductor package manufacturing method PM2 may be substantially the same as the semiconductor package manufacturing method PM1 except for further including a protective film attaching operation P142, and performing the wafer back polishing operation P152 after dicing. In FIGS. 11 to 13, the same reference numerals as in FIGS. 1 to 6 denote the same members. In FIGS. 11 to 13, descriptions already given with reference to FIGS. 1 to 6 may be briefly described or omitted.

The semiconductor package manufacturing method PM2 may include an operation P110 of preparing a wafer (14 of FIG. 2) including a circuit layer. In an implementation, a circuit layer may not be formed on the wafer (14 in FIG. 2) and only a wiring layer may be formed. The semiconductor package manufacturing method PM2 of FIG. 11 may not perform a backside polishing process of the wafer 14 after the operation of preparing the wafer including the circuit layer or the wiring layer.

The semiconductor package manufacturing method PM2 may include performing operations P130 to P200. Operations P130 to P200 may be semiconductor chip division (separation) processes. In an implementation, in operation P130, the wafer 14 may be mounted on the first support film 12. In operation P140, the wafer protective layer may be formed by coating the wafer protective coating composition 18 on the wafer 14 mounted on the first support film 12. The wafer protective layer has been described above, and a repeated description of the wafer protective layer may be omitted.

Subsequently, in operation P142, a protective film may be attached on the wafer protective layer. As shown in FIG. 12, the protective film 15 may be attached on the wafer 14 supported on the support frame 10 and attached on the first support film 12. The protective film 15 may be adhered on the wafer protective layer on the wafer 14 by rotating a roller 13 clockwise.

In operation P150, the wafer 14 (on which the wafer protective layer and the protective film have been formed) may be diced into semiconductor chips 24. The dicing process has been described above, and a repeated description thereof may be omitted. In operation P152, the back surface of the wafer 14 may be polished. The backside polishing of the wafer 14 may be a process of reducing the thickness of the wafer 14 by polishing the back surface of the wafer 14 by a grinding method in a state in which the wafer protective layer and the protective film are formed.

Next, in operation P154, the protective film may be removed. As shown in FIG. 13, the protective film 15 on the wafer 14 (which is supported by the support frame 10 and is adhered on the first support film 12) may be removed. The protective film may be removed from the wafer 14 by rotating the roller 13 counterclockwise.

In operation P160, the semiconductor chips 24 may be separated from each other by expanding the first support film 12. In operation P170, the semiconductor chips 24 may be transferred onto the second support film 28. In operation P180, the wafer protective layer coated on the semiconductor chips 24 may be removed by primary cleaning the wafer protective layer. In operation P190, any residual material left on the semiconductor chips may be detected. In operation P200, any residual material on the semiconductor chips 24 may be removed by secondary cleaning. Operations P160 to P200 have been described above, and repeated detailed descriptions thereof may be omitted.

In operation P210, the semiconductor package manufacturing method PM2 may include mounting semiconductor chips on a package substrate and performing a package process. The packaging process has been described above, and a repeated description thereof may be omitted.

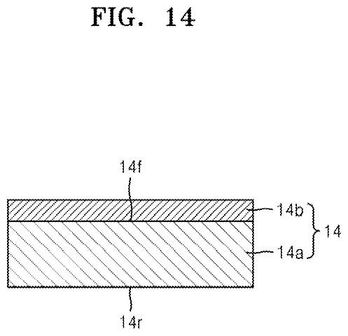

FIGS. 14 to 21 are cross-sectional views of stages in a method of manufacturing a semiconductor package according to an embodiment.

In detail, FIGS. 14 to 21 are provided to help explain the semiconductor package manufacturing method PM1 described with reference to FIGS. 1 to 6. In FIGS. 14 to 21, the same reference numerals as in FIGS. 1 to 6 denote the same members.

FIG. 14 helps explain an operation P110 of preparing a wafer 14 including a circuit layer (or an integrated circuit layer). A wafer 14 including a wafer body 14a and a circuit layer (integrated circuit layer) 14b may be prepared. In an implementation, the wafer 14 may include only a wiring layer, without a circuit layer formed thereon. The circuit layer 14b may be formed on the wafer body 14a. The wafer body 14a may include a front surface 14f and a back surface 14r.

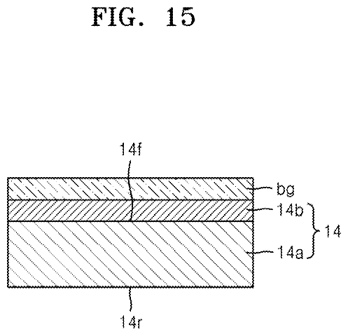

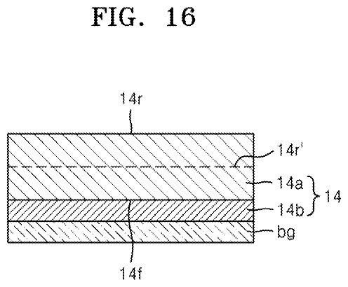

FIGS. 15 and 16 help explain the operation P120 of polishing the back surface of the wafer 14. As shown in FIG. 15, a backgrinding tape bg may be attached on the circuit layer 14b of the wafer 14. The backgrind tape bg may help protect the circuit layer 14b when the back surface 14r of the wafer body 14a is polished in a subsequent process.

As shown in FIG. 16, the wafer 14 may be turned over and the back surface 14r of the wafer body 14a may be polished by a grinding method to reduce the thickness of the wafer body 14a. Accordingly, the wafer body 14a may have a back surface 14r′.

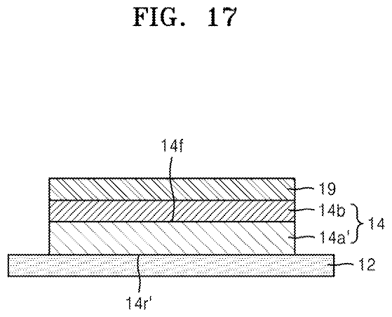

FIG. 17 helps explain the operation P130 of mounting the wafer 14 on the first support film 12 and the operation P140 of forming the wafer protective layer 19 on the wafer 14. After the backgrinding tape bg is removed, the wafer 14 may be mounted on the first support film 12. After the backside polishing of the wafer 14, the reference number of the wafer body 14a may be 14a′. The wafer body 14a′, e.g., the back surface 14r′ of the wafer body 14a′, may be mounted on the first support film 12.

The wafer protective layer 19 may be formed by coating the wafer protective coating composition (18 in FIG. 2) on the circuit layer 14b of the wafer 14. The coating composition for protecting the wafer has been described above, and a repeated description thereof may be omitted.

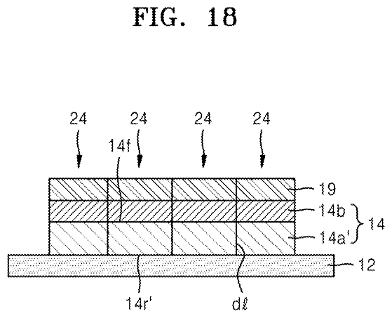

FIG. 18 helps explain the operation P150 of dicing the wafer 14 coated with the wafer protective layer 19. The wafer 14 (including the wafer protective layer 19 thereon) may be diced (cut) into semiconductor chips 24 along a dicing line dl. The dicing process has been described in detail above, and a repeated description thereof may be omitted.

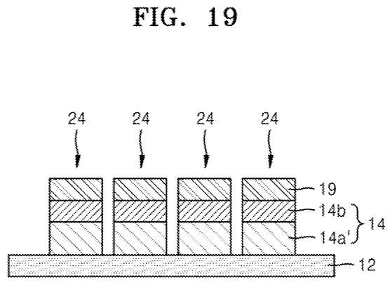

FIG. 19 helps explain the operation of separating the semiconductor chips 24 from each other by expanding the first support film 12. The gap between the semiconductor chips 24 may be increased by expanding the first support film 12. The expansion process of the first support film 12 may facilitate the transfer of the semiconductor chips 24 later.

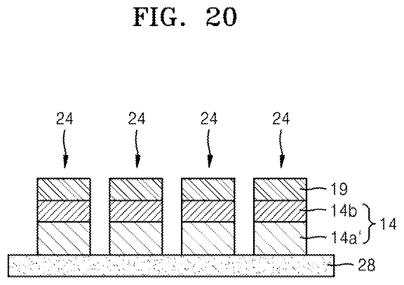

FIG. 20 helps explain an operation P170 of transferring the semiconductor chips 24 onto the second support film 28. The semiconductor chips 24 attached on the first support film 12 may be transferred onto the second support film 28. The process of transferring the semiconductor chips 24 onto the second support film 28 may facilitate transfer of the semiconductor chips 24 mounted on the package substrate later.

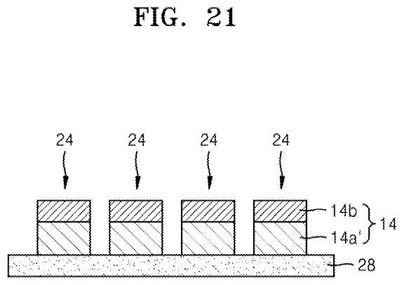

FIG. 21 helps explain an operation P180 of primary cleaning and removing the wafer protective layer 19 from the semiconductor chips 24. The wafer protective layer 19 on the semiconductor chips 24 (mounted on the second support film 28) may be removed using a cleaning solution (34 of FIG. 6). The cleaning solution may include, e.g., water or an alcohol.

Subsequently, as described with reference to FIG. 1, any residual material remaining on the semiconductor chips 24 may be detected (P190 of FIG. 1). Residual materials remaining on the semiconductor chips 24 may be removed through secondary cleaning (P200 in FIG. 1). In operation P210, the semiconductor chips 24 (from which the residual material has been removed) may be mounted on a package substrate to perform a package process.

The semiconductor package manufacturing method of FIGS. 14 to 21 described above mainly describes the semiconductor package manufacturing method PM1 of FIGS. 1 to 6, and may also be applied to the semiconductor package manufacturing method PM2 of FIGS. 11 to 13, except for the protective film attaching operation P142 and the wafer rear polishing operation P152 after dicing.

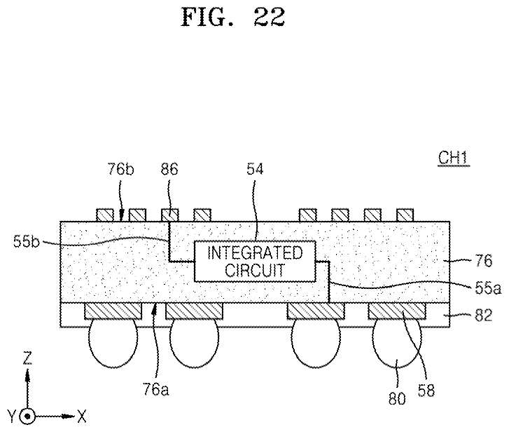

FIG. 22 is a cross-sectional view of a semiconductor chip that may be manufactured by a method of manufacturing a semiconductor package according to an embodiment.

In an implementation, a semiconductor chip CH1 may be manufactured by the wafer 14 of FIGS. 14 to 21. The semiconductor chip CH1 may correspond to the semiconductor chip 24 manufactured with reference to FIGS. 14 to 21. The wafer 76 may correspond to the wafer 14 of FIGS. 14 to 21. An integrated circuit 54 may correspond to the circuit layer 14b of FIGS. 14 to 21.

The semiconductor chip CH1 may be a memory chip or a logic chip including the integrated circuit 54. The integrated circuit 54 may be electrically connected to a first wiring pads 58 and solder bumps 80 on a first surface 76a of a wafer 76 using a first wiring layer 55a.

A passivation layer 82 may be formed between the first wiring pads 58 on the first surface 76a. The integrated circuit 54 may be electrically connected to second wiring pads 86 on a second surface 76b of the wafer 76 using a second wiring layer 55b.

In an implementation, the integrated circuit 54 may be electrically connected to the first wiring pads 58 and the second wiring pads 86 using a first wiring layer 55a and a second wiring layer 55b. In an implementation, the integrated circuit 54 may be electrically connected to the first wiring pads 58 and the second wiring pads 86 using a through silicon via structure.

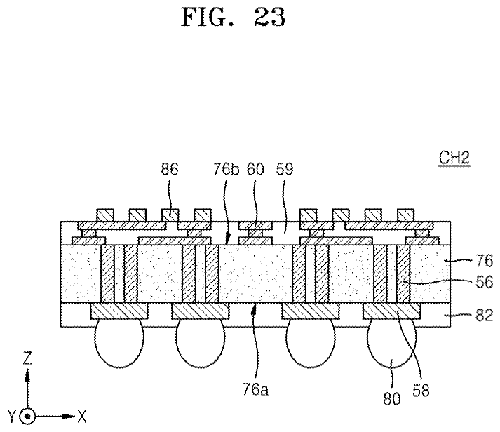

FIG. 23 is a cross-sectional view of a semiconductor chip that may be manufactured by the method of manufacturing a semiconductor package according to an embodiment.

In an implementation, a semiconductor chip CH2 may be manufactured by the method of FIGS. 14 to 21. The semiconductor chip CH2 may correspond to the semiconductor chip 24 manufactured with reference to FIGS. 14 to 21. A wafer 76 may correspond to the wafer 14 manufactured by FIGS. 14 to 21.

The semiconductor chip CH2 may be an interposer chip including a through-via structure 56, e.g., a through-silicon via structure. The through-via structure 56 may be electrically connected to first wiring pads 58 and solder bumps 80 on a first surface 76a of the wafer 76. A passivation layer 82 may be between the first wiring pads 58 on the first surface 76a.

The through-via structure 56 may be electrically connected to the second wiring pads 86 on a second surface 76b of the wafer 76 using a multilayer wiring layer 60. The multilayer wiring layer 60 may be in the interlayer insulating layer 59 on the second surface 76b of the wafer 76.

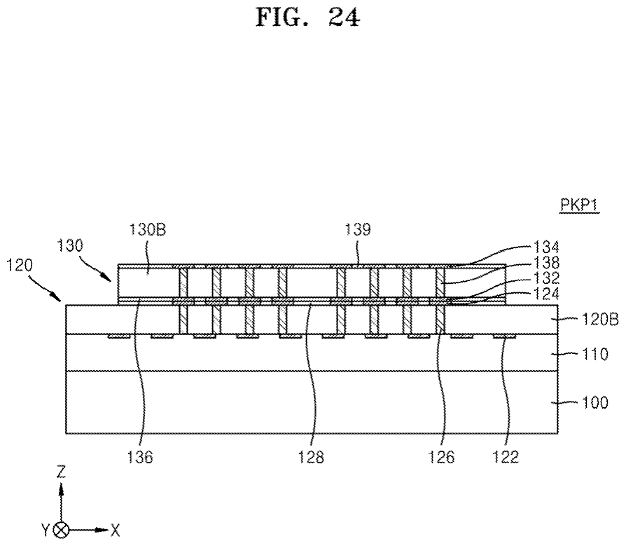

FIG. 24 is a cross-sectional view of a package process included in the method of manufacturing a semiconductor package according to an embodiment.

In an implementation, a package process PKP1 may include mounting the package substrate 120 on an adhesive layer 110 on a support frame 100. The package substrate 120 may be an interposer substrate or an interposer chip. The package substrate 120 may include a lower substrate pad 122 and an upper substrate pad 124 respectively on a lower surface and an upper surface of the substrate body 120B. The lower substrate pad 122 and the upper substrate pad 124 may be electrically connected to each other through a through-substrate via 126. The lower surface of the lower substrate pad 122 may be attached to an adhesive layer 110. A substrate pad insulating layer 128 may be between the upper substrate pads 124.

The package process PKP1 may include stacking and bonding a first semiconductor chip 130 on the package substrate 120. The first semiconductor chip 130 may correspond to the semiconductor chip 24 manufactured with reference to FIGS. 14 to 21. The first semiconductor chip 130 may include a first chip lower surface pad 132 and a first chip upper surface pad 134 respectively formed on a lower surface and an upper surface of a first chip body 130B. The first chip lower surface pad 132 and the first chip upper surface pad 134 may be electrically connected to each other through a first chip through via 138. A first chip lower pad insulating layer 136 may be formed between the first chip lower surface pads 132. A first chip upper pad insulating layer 139 may be formed between the first chip upper surface pads 134.

The upper substrate pad 124 of the substrate may be directly bonded to the first chip lower surface pad 132. When a residual material is removed from or otherwise does not remain on the first chip lower surface pad 132 and the first chip upper surface pad 134 by the semiconductor package manufacturing method of an embodiment, there may be high bonding reliability between the upper substrate pad 124 of the substrate and the first chip lower surface pads 132, thereby reducing semiconductor package defects.

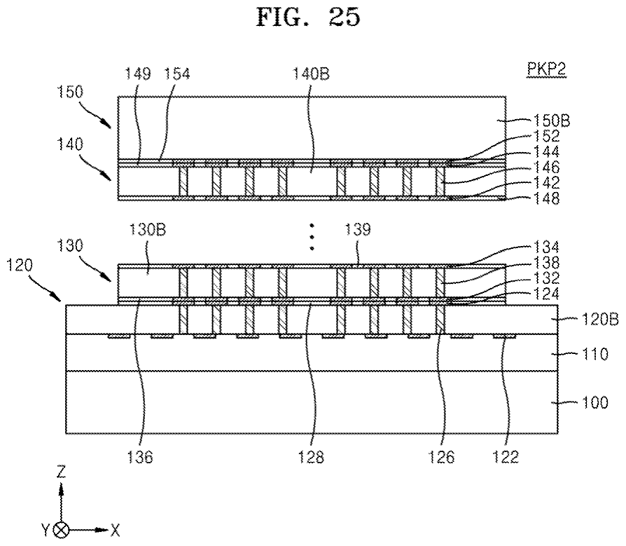

FIG. 25 is a cross-sectional view illustrating a package process included in a method of manufacturing a semiconductor package according to an embodiment.

In an implementation, a package process PKP2 is the same as the package process PKP1 of FIG. 24 except for further stacking and bonding a second semiconductor chip 140 and a third semiconductor chip 150 on a first semiconductor chip 130.

The package process PKP2 may include mounting a package substrate 120 on an adhesive layer 110 on a support frame 100, and laminating and bonding the first semiconductor chip 130 on the package substrate 120. Such mounting of the package substrate 120 and the stacking and bonding of the first semiconductor chip 130 may be the same as described above with reference to FIG. 24, and a repeated description thereof may be omitted.

The package process PKP2 may include stacking and bonding the second semiconductor chip 140 on the first semiconductor chip 130. The second semiconductor chip 140 may correspond to the semiconductor chip 24 manufactured with reference to FIGS. 14 to 21. The second semiconductor chip 140 may include a second chip lower surface pad 142 and a second chip upper surface pad 144 respectively on a lower surface and an upper surface of the second chip body 140B. The second chip lower surface pad 142 and the second chip upper surface pad 144 may be electrically connected to each other through a second chip through via 146. A second chip lower pad insulating layer 148 may be between the second chip lower surface pads 142. A second chip upper pad insulating layer 149 may be between the second chip upper surface pads 144.

The second chip lower surface pad 142 may be directly bonded to a first chip upper surface pad 134. When a residual material is removed from or otherwise does not remain on the second chip lower surface pad 142 and the first chip upper surface pad 134 by the semiconductor package manufacturing method of an embodiment, the bonding reliability between the second chip lower surface pad 142 and the first chip upper surface pad 134 may be high, thereby reducing semiconductor package defects.

The package process PKP2 may include stacking and bonding the third semiconductor chip 150 on the second semiconductor chip 140. The third semiconductor chip 150 may correspond to the semiconductor chip 24 manufactured with reference to FIGS. 14 to 21. The third semiconductor chip 150 may include a third chip lower surface pad 152 on a lower surface of the third chip body 150B. A third chip pad insulating layer 154 may be between the third chip lower surface pads 152.

The third chip lower surface pad 152 may be directly bonded to the second chip upper surface pad 144. When a residual material has been removed from or otherwise does not remain on the third chip lower surface pad 152 and the second chip upper surface pad 144 by the semiconductor package manufacturing method of an embodiment, the bonding reliability between the third chip lower surface pad 152 and the second chip upper surface pad 144 may be high, thereby reducing semiconductor package defects.

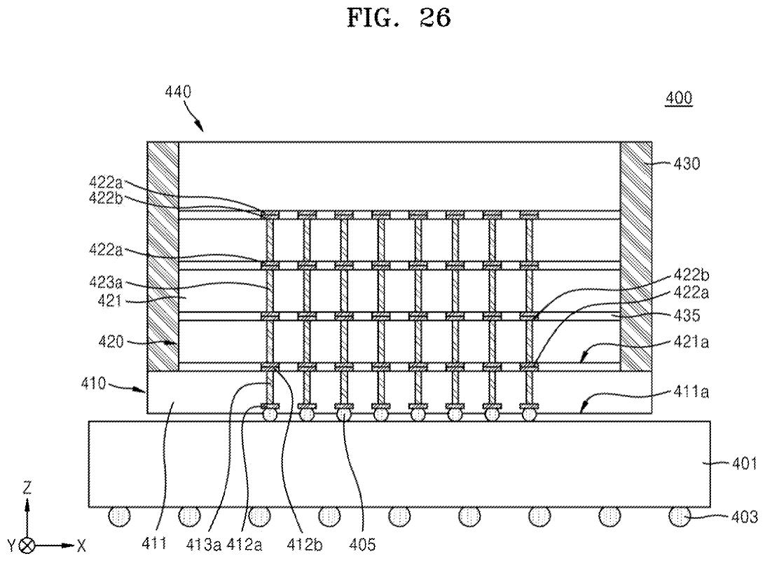

FIG. 26 is a cross-sectional view showing a semiconductor package manufactured by the method of manufacturing a semiconductor package according to an embodiment.

In an implementation, a semiconductor package 400 may include a stacked semiconductor chip 440 stacked on a package substrate 401. The package substrate 401 may be a printed circuit board. Each of the stacked semiconductor chips 440 may correspond to the semiconductor chip 24 manufactured with reference to FIGS. 14 to 21. Solder bumps 403 that are external connection terminals may be on a lower surface of the package substrate 401.

The stacked semiconductor chip 440 may include a first semiconductor chip 410 and a plurality of second semiconductor chips 420 mounted on the first semiconductor chip 410. The second semiconductor chips 420 may be sequentially stacked on the first semiconductor chip 410 in a vertical direction (Z direction). A width of the first semiconductor chip 410 may be greater than a width of each of the second semiconductor chips 420.

In an implementation, as illustrated in FIG. 26, the stacked semiconductor chip 440 may include four second semiconductor chips 420. In an implementation, the stacked semiconductor chip 440 may include two or more second semiconductor chips 420.

The first semiconductor chip 410 may include a first pad 412a and a second pad 412b on both surfaces of a first semiconductor substrate 411. The first pad 412a and the second pad 412b may be electrically connected to each other using a first through-via structure 413a.

The first pad 412a may be electrically connected to the package substrate 401 using a solder bump 405 that is an external connection terminal. The first semiconductor chip 410 may have an active surface 411a thereunder. The first pad 412a may be an upper surface pad. The second pad 412b may be a lower surface pad. The second pad 412b may be directly bonded to the third pad 422a of the lowermost second semiconductor chip 420.

When a residual material has been removed from or otherwise does not remain on the second pad 412b and a third pad 422a by the semiconductor package manufacturing method of an embodiment, the bonding reliability between the second pad 412b and the third pad 422a may be high, thereby reducing semiconductor package defects.

Each of the second semiconductor chips 420 may include a third pad 422a and a fourth pad 422b on both surfaces of the second semiconductor substrate 421. The second semiconductor chip 420 located at the uppermost portion may be disposed with the third pad 422a only on the lower surface thereof. The third pad 422a and the fourth pad 422b may be electrically connected to each other using a second through-via structure 423a. The third pad 422a may be directly bonded to and connected to the fourth pad 422b.

Each of the second semiconductor chips 420 may have an active surface 421a thereunder. The third pad 422a may be an upper surface pad. The fourth pad 422b may be a lower surface pad. When a residual material has been removed from or otherwise does not remain on the third pad 422a and the fourth pad 422b by the semiconductor package manufacturing method of an embodiment, the bonding reliability between the third pad 422a and the fourth pad 422b may be high, thereby reducing semiconductor package defects.

In the stacked semiconductor chip 440, the second semiconductor chips 420 may be bonded to each other by an adhesive layer 435. The second semiconductor chips 420 may be molded on the first semiconductor chip 410 by the molding layer 430.

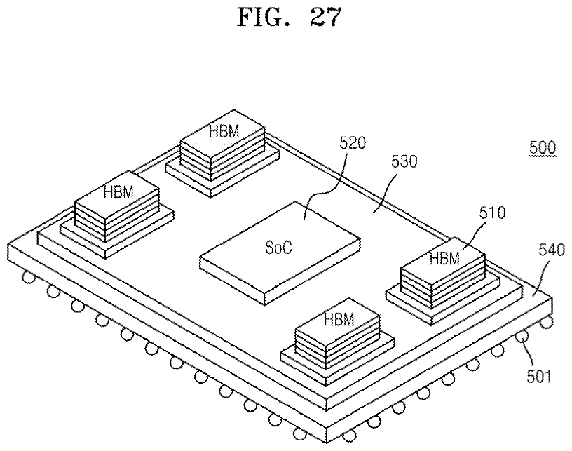

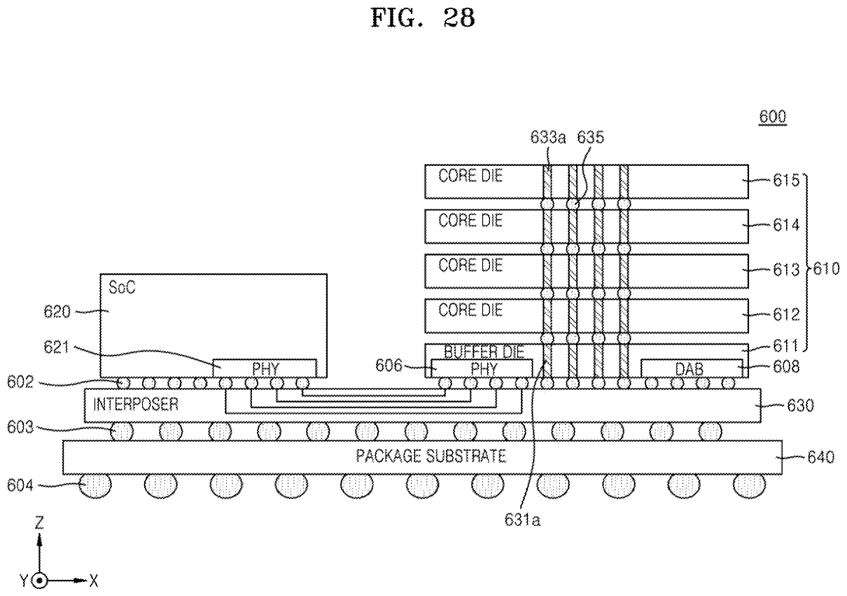

FIGS. 27 and 28 are views illustrating a semiconductor package manufactured by a method of manufacturing a semiconductor package according to an embodiment.

Referring to FIG. 27, a semiconductor package 500 may include a plurality of stacked memory chips 510 and a system-on-chip (SoC) 520. The stacked memory chips 510 and the system-on-chip 520 may be stacked on an interposer chip 530, and the interposer chip 530 may be stacked on a package substrate 540.

Each of the interposer chip 530 and the stacked memory chips 510 may correspond to the semiconductor chip 24 manufactured with reference to FIGS. 14 to 21. Accordingly, in the semiconductor package 500, bonding reliability between the respective members may be improved, thereby reducing semiconductor package defects.

The semiconductor package 500 may transmit/receive signals to and from other external packages or electronic devices through solder balls 501 attached to the lower portion of the package substrate 540. In an implementation, each of the stacked memory chips 510 may be implemented based on the HBM standard. In an implementation, each of the stacked memory chips 510 may be implemented based on GDDR, HMC, or wide I/O standards.

The system-on-chip 520 may include at least one processor such as a CPU, an AP, a GPU, and an NPU and a plurality of memory controllers for controlling a plurality of stacked memory chips 510. The system-on-chip 520 may transmit/receive signals to and from a corresponding stacked-type memory chip through a memory controller.

Referring to FIG. 28, a semiconductor package 600 may include a stacked memory chip 610, a system on chip 620, an interposer chip 630, and a package substrate 640. The stacked memory chip 610, the system-on-chip 620, and the interposer chip 630 may correspond to the semiconductor chip 24 manufactured with reference to FIGS. 14 to 21. Accordingly, in the semiconductor package 600, bonding reliability between the respective members may be improved, thereby reducing semiconductor package defects.

The stacked memory chip 610 may include a buffer die 611 and core dies 612 to 615. Each of the core dies 612 to 615 may include memory cells for storing data. The buffer die 611 may include a physical layer (PHY) 606, and a direct access region DAB 608. The physical layer 606 may be electrically connected to a physical layer 621 of the system-on-chip 620 through the interposer chip 630. The stacked memory chip 610 may receive signals from the system-on-chip 620 or transmit signals to the system-on-chip 620 through the physical layer 606.

The direct access region DAB 608 may provide an access path for testing the stacked memory chip 610 without going through the system on chip 620. The direct access region DAB 608 may include conductors (e.g., ports or pins) that may communicate directly with an external test device. A test signal received through the direct access region DAB 608 may be transmitted to the core dies 612 to 615 through through-via structures. For testing of the core dies 612 to 615, data read from the core dies 612 to 615 may be transmitted to a test device through the through-via structures and the direct access region DAB 608. Accordingly, a direct access test for the core dies 612 to 615 may be performed.

The buffer die 611 and the core dies 612 to 615 may be electrically connected to each other through through-via structures 631a and 633a and bumps 635. In an implementation, the buffer die 611 may include a first through-via structure 631a. Each of the core dies 612 to 615 may include a second through-via structure 633a. The buffer die 611 may receive signals provided to each channel from the system-on-chip 620 through bumps 602 allocated for each channel, or may transmit signals to the system on chip 620 through bumps 602. In an implementation, the bumps 602 may be micro bumps.

The system on chip 620 may execute applications supported by the semiconductor package 600 using the stacked memory chip 610. The system-on-chip 620 may include a central processing unit (CPU), an application processor (AP), a graphics processing unit (GPU), a neural processing unit (NPU), a tensor processing unit (TPU), a vision processing unit (VPU), an image signal processor (ISP), or a digital signal processor (DSP) to execute specialized operations.

The system-on-chip 620 may control the overall operation of the stacked memory chip 610. The system on chip 620 may include the physical layer 621. The physical layer 621 may include an interface circuit for transmitting and receiving signals to and from the physical layer 606 of the stacked memory chip 610. The system-on-chip 620 may provide various signals to the physical layer 606 through the physical layer 621. Signals provided to the physical layer 606 may be transmitted to the core dies 612 to 615 through an interface circuit of the physical layer 606 and through-via structures 631a and 633a.

The interposer chip 630 may connect the stacked memory chip 610 to the system-on-chip 620. The interposer chip 630 may connect the physical layer 606 of the stacked memory chip 610 and the physical layer 621 of the system-on-chip 620 and provide physical paths formed using conductive materials. Accordingly, the stacked memory chip 610 and the system-on-chip 620 may be stacked on the interposer chip 630 to transmit/receive signals to and from each other.

Bumps 603 may be attached to an upper portion of the package substrate 640, and solder balls 604 may be attached to a lower portion of the package substrate 640. In an implementation, the bumps 603 may be flip-chip bumps. The interposer chip 630 may be stacked on the package substrate 640 through the bumps 603. The semiconductor package 600 may transmit/receive signals to/from other external packages or electronic devices through the solder ball 604. In an implementation, the package substrate 640 may be a printed circuit board (PCB).

By way of summation and review, in a dicing process, a wafer protective layer may be formed to help protect the semiconductor chips. The wafer protective layer may be a contamination source and could cause defects in the semiconductor package.

One or more embodiments may provide a coating composition wafer protection, used for wafer dicing.

One or more embodiments may provide a coating composition for wafer protection that may help prevent it from acting as a contamination source.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A coating composition for wafer protection, the coating composition comprising:
a solvent;
about 1 weight percent (wt %) to about 40 wt % of a water-soluble polymer; and
about 0.01 wt % to about 30 wt % of a nano light-emitting filler.

2. The coating composition as claimed in claim 1, wherein the water-soluble polymer includes polyvinyl alcohol (PVA), polyvinyl pyrrolidone (PVP), polyethylene glycol (PEG), cellulose, polyoxazoline, polyacrylic acid (PAA), polyacrylamide, or combinations thereof.

3. The coating composition as claimed in claim 1, wherein the nano light-emitting filler includes Li, Na, K, Mg, Ca, Sr, Ba, Ti, Zr, Hf, V, Nb, Ta, Cr, Mo, W, Mn, Fe, Ru, Co, Ni, Pd, Pt, Cu, Ag, Au, Zn, B, Al, Ga, In, Si, Ge, Sn, As, Bi, La, Ce, Pr, Gd, Yb, Tb, Lu, Sm, or combinations thereof.

4. The coating composition as claimed in claim 3, wherein the nano light-emitting filler further includes C, N, O, P, S, F, Cl, Br, Se, Te, or combinations thereof.

5. The coating composition as claimed in claim 1, wherein the nano light-emitting filler includes a phosphor or quantum dots.

6. The coating composition as claimed in claim 1, wherein a size of the nano light-emitting filler is about 1 nm to about 999 nm.

7. The coating composition as claimed in claim 1, wherein the nano light-emitting filler has an excitation wavelength in the ultraviolet range, and emits light having an emission wavelength in the visible light range when light in the ultraviolet range is applied.

8. The coating composition as claimed in claim 7, wherein the nano light-emitting filler has an excitation wavelength of about 200 nm to about 450 nm and an emission wavelength of about 390 nm to about 650 nm.

9. The coating composition as claimed in claim 1, wherein the coating composition for wafer protection has a viscosity of about 10 cP to about 500 cP.

10. A method of manufacturing a semiconductor package, the method comprising:
preparing a wafer including a circuit layer or a wiring layer;
forming a wafer protective layer by coating a coating composition for wafer protection on the wafer, the coating composition for wafer protection including a solvent, about 1 weight percent (wt %) to about 40 wt % of a water-soluble polymer, and about 0.01 wt % to about 30 wt % of a nano light-emitting filler;
dicing the wafer on which the wafer protection layer is formed, into semiconductor chips; and
removing the wafer protective layer from the semiconductor chips by primary cleaning the wafer protective layer;
wherein primary cleaning the wafer protective layer includes detecting residual material remaining on the semiconductor chips.

11. The method as claimed in claim 10, further comprising, after removing the wafer protective layer by primary cleaning the wafer protective layer,
removing the residual material from the semiconductor chips by secondary cleaning; and
performing a package process using the semiconductor chips.

12. The method as claimed in claim 11, wherein detecting the residual material remaining on the semiconductor chips includes irradiating ultraviolet light onto the semiconductor chips and detecting visible light emitted from the semiconductor chips.

13. The method as claimed in claim 10, further comprising, after the preparing of the wafer, polishing a back surface of the wafer.

14. The method as claimed in claim 10, wherein:
dicing the wafer into the semiconductor chips is performed on a first support film,
the method further includes, after dicing the wafer into the semiconductor chips:
expanding the first support film to separate the diced semiconductor chips from each other on the expanded first support film; and
transferring the separated semiconductor chips onto a second support film.

15. The method as claimed in claim 10, further comprising attaching a protective film onto the wafer protective layer after forming the wafer protective layer.

16. A method of manufacturing a semiconductor package, the method comprising:
preparing a wafer including a circuit layer or a wiring layer;
mounting the wafer on a first support film;
forming a wafer protective layer by coating a coating composition for wafer protection on the wafer, the coating composition for wafer protection including a solvent, about 1 weight percent (wt %) to about 40 wt % of a water-soluble polymer, and about 0.01 wt % to about 30 wt % of a nano light-emitting filler;
dicing the wafer, on which the wafer protection layer has been formed, into semiconductor chips;
separating the semiconductor chips by expanding the first support film;
transferring and mounting the separated semiconductor chips onto a second support film; and
removing the wafer protective layer from the semiconductor chips mounted on the second support film by primary cleaning the wafer protective layer;
wherein primary cleaning the wafer protective layer includes detecting residual material remaining on the semiconductor chips.

17. The method as claimed in claim 16, further comprising, after removing the wafer protective layer by the primary cleaning of the wafer protective layer,
removing the residual material from the semiconductor chips by secondary cleaning the residual material on the second support film; and
performing a package process by transferring the semiconductor chips from the second support film.

18. The method as claimed in claim 16, further comprising polishing a back surface of the wafer after preparing the wafer including the circuit layer or the wiring layer.

19. The method as claimed in claim 16, further comprising attaching a protective film onto the wafer protective layer after forming the wafer protective layer.

20. The method as claimed in claim 19, further comprising polishing a back surface of the wafer; and removing the protective film, after dicing the wafer into the semiconductor chips.
